(19) United States
(12) Patent Application Publication
(10) Pub. No.: US 2025/0115770 A1
(43) Pub. Date: Apr. 10, 2025

(54) COMPOSITIONS AND METHODS FOR FORMING METAL ORGANIC FRAMEWORK (MOF) FILMS AND RELATED MICROELECTRONIC DEVICES

(71) Applicant: Brewer Science, Inc., Rolla, MO (US)

(72) Inventors: Reuben T. Chacko, Rolla, MO (US); Stephen R. Murphy, Rolla, MO (US)

(21) Appl. No.: 18/912,542

(22) Filed: Oct. 10, 2024

Related U.S. Application Data
(60) Provisional application No. 63/543,307, filed on Oct. 10, 2023.

(51) Int. Cl. C09D 5/00; C09D 7/63; H01L 27/146

(52) U.S. Cl. CPC C09D 5/006; C09D 7/63; H10F 39/8063

(57) ABSTRACT

Materials that are processable as spin coated films with a refractive index of less than about 1.25 are presented. These compositions include metal organic frameworks in a solvent system, with the MOFs including a metal or metal cluster (e.g., zirconium oxide) having organic linkers (e.g., maleic acid, benzene dicarboxylic acid) and optional endcaps to alter pore size, compositional stability, steric, and other properties of the material. The formed films are processable at low temperatures, thus allowing them to be processed on plastics. The provided materials find use in, for example, silicon photonics, augmented reality applications, virtual reality (VR) applications, CMOS image sensors, and micro-OLED applications.

### CROSS-REFERENCE TO RELATED APPLICATIONS

The present application claims the priority benefit of U.S. Provisional Patent Application Ser. No. 63/543,307, filed Oct. 10, 2023, entitled COMPOSITIONS AND METHODS FOR FORMING METAL ORGANIC FRAMEWORK (MOF) FILMS AND RELATED MICROELECTRONIC DEVICES, the entirety of which is incorporated by reference herein.

### BACKGROUND

### Field

The present disclosure relates generally to low refractive index (RI) films and more particularly to materials that can be applied to substrates (e.g., by spin coating and/or dip coating) to form such low-RI films.

### Description of Related Art

Low-RI films are needed for a wide variety of applications in the semiconductor and microelectronic industry. For example, low-RI materials are commonly used today as antireflective films covering micro-lenses in CMOS image sensor devices. Low-RI materials are also needed for various antireflective coatings made by applying alternating layers of low-RI materials and high-RI materials. Low-RI materials are also used to form optical waveguides for use in photonics and many other different microelectronic devices. These are just a few examples of the numerous applications for low-RI materials in semiconductor device manufacturing.

Low-RI materials are often used as films having a thickness designed to be ¼ the wavelength of the targeted light. For visible antireflective coatings, the wavelengths are centered at 550 nm, and thus, these low-RI films are typically deposited at thicknesses of around 90 to 140 nm. The ideal refractive index of such films for optical performance depends on the refractive index of air as well as the refractive index of the substrate supporting the films. Commonly, the ideal refractive index is lower than 1.25, but materials having refractive indices this low are not widely used because the processing requirements of the materials can be harsh and incompatible with other processing requirements. Also, low-RI materials also have a variety of other trade-offs that make them difficult to use in commercial applications. Thus, low-RI materials in commercial applications commonly have a sub-optimally high refractive index. Accordingly, there is a large unmet demand for commercially workable low-RI materials having even lower RI.

Additionally, most spin-coated low-RI films have numerous small pores within them. Generating these pores typically requires spin coating a film-forming material on the substrate, followed by processing at relatively high temperatures to generate the pores. A number of these films are formed using solgels of siloxanes with methyl trimethoxy silane (MTMS) and tetraethoxy silane (TEOS) as precursors. Porosity is introduced into the films using porogens such as block copolymers, polymeric beads, or other particles that are removed pyrolytically after the precursor has been applied to the substrate. These films require higher temperatures to achieve pyrolytic removal of such porogens and generate pores. This requirement to process the low-RI film-forming material on the substrate at high temperature is often incompatible with plastic substrates which require lower temperatures, typically no more than 125° C., and may also make them unsuitable for fab friendly processes that require times and temperatures to be relatively short and below solder reflow temperatures of 260° C. For several technological applications, such temperatures are not process compatible.

Shelf-life of low-RI film-forming compositions is also a problem with many prior art low-RI materials. They are often only processible according to their design for only a relatively brief time before gelation and other problems start to become problematic. Aging can also result in problems hitting target thicknesses and/or the target refractive indices.

Thus, there is a need for better low-RI films and film-forming compositions that are processible under less demanding conditions that are more compatible with a wider variety of processes.

### SUMMARY

The present disclosure is broadly concerned with a method of forming a low refractive index film. The method comprises applying a composition to a substrate, with the composition comprising a metal organic framework in a solvent system. The metal organic framework includes an organic linker having a thermal decomposition temperature. The composition is heated to a temperature of no higher than about 10° C. below the thermal decomposition temperature to form the low refractive index film.

The disclosure also provides a structure comprising a low refractive index film on a substrate. The low refractive index film comprises a metal organic framework comprising a plurality of metal clusters coordinated to respective organic linkers. The majority of the metal clusters are crosslinked with at least one other metal cluster. The low refractive index film has a refractive index of about 1.35 or lower at a wavelength of about 200 nm or greater. The substate is chosen from glass, polycarbonate, one or more micro lenses, a lens body, patterned substrates, silicon nitride, or high RI substrates.

### BRIEF DESCRIPTION OF THE DRAWINGS

FIG. 1 is a schematic illustration of a complementary metal oxide semiconductor (“CMOS”) image sensor fabrication process;

FIG. 2 is a graph of the % T vs. wavelength of the samples tested in Example 2;

FIG. 3 is a graph of the % T vs. wavelength of the samples tested in Example 3;

FIG. 4 is a graph comparing the % T of a polycarbonate control and a dip-coated sample (Example 5);

FIG. 5 is a graph comparing the % T of a polycarbonate control and a dip-coated sample (Example 6);

FIG. 6 is a graph comparing the % T of a polycarbonate control and a dip-coated sample (Example 7);

FIG. 7 is a graph showing the n and k values of a sample film, determined as described in Example 8;

FIG. 8 is a graph comparing the % T of three test films to a polycarbonate control (Example 8);

FIG. 9 is a graph of the % T vs. wavelength of the samples tested in Example 9;

FIG. 10 is a graph of the % T vs. wavelength of samples dip coated using different movement rates and dry times (Example 10);

FIG. 11 is a graph of the % T vs. wavelength of samples dip coated using different movement rates and dry times (Example 11);

FIG. 12 is a scanning electron microscope (“SEM”) image (100 kX) showing the gap fill performance of a low-RI film disclosed herein (Example 17);

FIG. 13 is an SEM (100 kX) showing the gap fill performance of a low-RI film disclosed herein (Example 17); and

FIG. 14 is a graph of % R vs. wavelength of the sample tested in Example 18 as compared to a polycarbonate control.

### DETAILED DESCRIPTION

The present disclosure is concerned with materials or compositions useful for forming low-RI films, and the methods of forming those films. These compositions broadly comprise a metal organic framework (MOF) in a solvent system.

### Compositions

### 1. MOFs

The metal organic frameworks are generally crystalline materials comprising metal ions or metal clusters coordinated with an organic linker. The metal ions or metal clusters include one or more of Li, Na, K, Rb, Cs, Fr, Be, Mg, Ca, Sr, Ba, Ra, Sc, Y, Ti, Zr, Hf, La, Ac, V, Nb, Ta, Ce, Th, Cr, Mo, W, Pr, Pa, Mn, Tc, Re, Nd, U, Fe, Ru, Os, Pm, Np, Co, Rh, Ir, Sm, Pu, Ni, Pd, Pt, Eu, Am, Cu, Ag, Au, Gd, Cm, Zn, Cd, Hg, Tb, B, Al, Ga, In, Tl, Dy, Si, Ge, Sn, Pb, Ho, As, Sb, Bi, Er, Te, Po, Tm, At, Yb, Lu, or combinations thereof. In some embodiments, the metal is provided as an oxide of one or more of the foregoing metals.

The MOF will typically include about 7.5% to about 70% by weight metal oxide, more preferably about 10% to about 30% by weight metal oxide, and even more preferably about 15% to about 25% by weight metal oxide, based upon the total weight of the MOF taken as 100% by weight.

Suitable organic linkers include ditopic, tritopic, tetratopic, or multitopic ligands and are typically oxygen-and/or nitrogen-based ligands. These linkers will undergo coordination reactions with the metal ions or metal clusters under certain catalysis and temperature conditions and generate coordination bonds through coordination reactions. “Hard” acids such as those including —COOH groups will typically coordinate with higher valence metals like zirconium while azoles will typically bind with lower valence metals such as zinc.

Preferred organic linkers include those chosen from dicarboxylic acids (e.g., benzene dicarboxylic acid, maleic acid, biphenyl dicarboxylic acid, 2,5-dihydroxyterephthalic acid, fumaric acid, ethanedioic acid, propanedioic acid, naphthalene dicarboxylic acid, aminoterphthalic acid and its derivatives, sulfoterephthalate and its derivatives), tricarboxylic acids (e.g., trimesic acid), azoles including imidazoles (e.g., 4H-imidazole, 2-methylimidazole) and triazoles (e.g., 1H-1,2,3-triazole, 1H-1,2,4-triazole), pyridines (e.g., 4,4-bipyridine, 4,4-azopyridine), or combinations thereof.

The MOF will typically include about 8% to about 90% by weight organic linker, more preferably about 10% to about 60% by weight organic linker, and even more preferably about 15% to about 40% by weight organic linker, based upon the total weight of the MOF taken as 100% by weight.

In one or more embodiments, the MOF will include an endcap, which could be bonded to the metal oxide clusters, the organic linkers, or both, and can also be referred to as a defect-introducing unit and/or a non-linker unit. Endcaps can be used to modulate the Lewis acid sites in the MOF, catalyze MOF formation, or both. Suitable endcaps include acids, and particularly monofunctional acids, such as alkyl (e.g., C₁-C_{18,} preferably C₁-C₁₂) carboxylic acids, aryl (e.g., C₁-C_{13,} preferably C₁-C₁₂) carboxylic acids, or combinations thereof. Endcap examples include trifluoroacetic acid, 9-anthracene carboxylic acid, propiolic acid, vinyl benzoic acid, vinyl phosphonic acid, acetic acid, formic acid, dichloroacetic acid, proline, phenylalanine, glycine, hydrochloric acid, alkoxy silanes (preferably C₁-C₅ alkoxy silanes, such as methyltrimethoxysilane tetraethoxysilane, isobutyltrimethoxysilane, phenyltrimethoxysilane, nonafluorohexyltriethoxysilane, 2-(3,4-epoxycyclohexyl)ethyltrimethoxy-silane, or combinations thereof), butyl glycidyl ether, or combinations of the foregoing.

In embodiments where an endcap is included, the MOF will typically include about 5% to about 75% by weight endcap, more preferably about 20% to about 60% by weight endcap, and even more preferably about 25% to about 55% by weight endcap, based upon the total weight of the MOF taken as 100% by weight.

In some embodiments, the molar ratio of metal oxide to organic linker is about 1:14 to about 1:1, preferably about 1:7 to about 1:1, and more preferably about 1:5 to about 1:2. In embodiments including an endcap, the molar ratio of metal oxide to endcap is about 1:15 to about 1:0.5, preferably about 1:7 to about 1:2, and more preferably about 1:6 to about 1:3, and/or the molar ratio of organic linker to endcap is about 1:0.1 to about 1:14, preferably about 1:0.3 to about 1:7, and more preferably about 1:0.35 to about 1:5.

Suitable MOFs have an average particle size of less than about 20 nm, preferably about 1 nm to about 20 nm, more preferably about 3 nm to about 17 nm, and even more preferably about 5 nm to about 15 nm. As used herein, “average particle size” refers to the average of the largest exterior (i.e., “surface-to-surface”) dimension of the MOF particles and is measured by SEM image analysis.

Additionally or alternatively, the MOFs used herein have an average pore size of about 1 nm to about 5 nm, preferably about 1 nm to about 3 nm, and more preferably about 1 nm to about 2.5 nm. “Average pore size” refers to the average of the largest dimension of the pores within the MOF and is determined by powder XRD.

The MOF can be made following conventional MOF formation methods, specific examples of which are found in the Examples section below. Alternatively, commercially available MOFs can be used, including modified (e.g., with an endcap and/or additional linker) and/or unmodified versions of those known as Al-Fum, Al-MIL-53-NH2, CAU-1-NH2, CAU-10, DUT-5, DUT-8, NH2-UiO-66, NO2-UIO-66, NU-1000, UiO-66, UiO-67, UIO-68, MIL-53, NH2-MIL-53, MIL-47, MIL-68, MIL-96, MIL-100, F-free MIL-100, ZIF-8, MIL-101, MIL-101(A1)-NH2, NH2-MIL-101, MIL-125, MIL-68, MIL-88A, MIL-88B, NH2-MIL-88B, HKUST-1, MOF-5, MOF-74, MOF-77, MOF-210, MOF-200, MOF-177, MOF-253, MOF-303, 467-MOF(A1), MOF-801, MOF-808, CAU-10, CAU-21 (A1), isophthalate; Al=0.9-1.0, PCN-128, PCN-222, PCN-223, PCN-224, PCN-777, PCN-250, PCN-600, PCN-333, Co/DOBC, ZIF-67, ZIF-9, Co(5-NH2-bdc), or combinations thereof.

The MOF will preferably be present at a level of about 1% to about 15% by weight, more preferably about 2% to about 10% by weight, and even more preferably about 3% to about 7% by weight, based upon the total weight of the composition taken as 100% by weight. Additionally or alternatively, on a solids basis the MOF is typically present at levels of about 30% by weight or greater, preferably about 50% by weight or greater, more preferably about 80% by weight or greater, even more preferably about 90% by weight or greater, and most preferably about 95-100% by weight, based upon the total weight of all solids present in the composition taken as 100% by weight.

### 2. Solvent System

The solvent system can comprise one or more solvents, with organic solvents being preferred. Typical total solids contents of the compositions will range from about 1% to about 60% by weight, and preferably from about 30% to about 45% by weight, based upon the total weight of the composition taken as 100% by weight, with the balance of the composition being solvent(s). Examples of solvents that can be used in the composition include those chosen from alcohols (e.g., methanol, ethanol), propylene glycol monomethyl ether acetate (“PGMEA”), propylene glycol methyl ether (“PGME”), dimethylsulfoxide (“DMSO”), propylene glycol ethyl ether (“PGEE”), propylene glycol n-propyl ether (“PnP”), ethyl lactate, cyclohexanone, gamma-butyrolactone (“GBL”), methyl isobutyl carbinol 3-methyl-1,5-pentanediol, 1,2-propylene glycol, 1,3-propylene glycol, ethylene glycol, cyclopentanone, or mixtures thereof.

### 3. Additional Components

The compositions can include one or more of a catalyst (also referred to as a modulator), a crosslinker, and/or a silane. Suitable catalysts include trifluoracetic acid (which can also be an endcap, as described above), acetic acid, formic acid, dichloroacetic acid, proline, phenylalanine, glycine, hydrochloric acid, or mixtures thereof. When a catalyst is included, it is preferably present in the composition at a level of about 0.1% to about 60% by weight, more preferably about 10% to about 35% by weight, even more preferably about 15% to about 30% by weight, based upon the total weight of the MOF taken as 100% by weight.

Crosslinkers maybe added to the formulation as an additive, or they may be attached to the MOF via grafting reactions. When added to the MOF as a graft the derivatized MOF may be further purified. Suitable crosslinkers that may be added to the final formulation as an additive include di- or multi-functional compounds, such as those including at least two functional groups chosen from vinyl groups, epoxy groups, hydroxy groups, carboxy groups, amine groups, or combinations thereof. Examples of crosslinkers for use in the compositions herein include those chosen from glycidyl polyhedral oligomeric silsesquioxane, methacrylate polyhedral oligomeric silsesquioxane, solgel derived siloxanes or similar oxides (e.g., alumina, other metal oxides), divinylbenzene, glycidyl methacrylate, or combinations thereof. When a crosslinker is added to the formulation without further processing, it is preferably present in the composition at a level of about 0.1% to about 30% by weight, more preferably about 0.25% to about 25% by weight, and even more preferably about 1% to about 15% by weight, based upon the total weight of the MOF taken as 100% by weight.

Some crosslinkers are grafted to the MOF cluster. Examples of such crosslinkers for use in the compositions herein include those chosen from glycidyl methacrylate, solgel derived siloxanes or similar oxides, silane monomers, or combinations thereof. Silanes can be included in the composition in applications where a siloxane film is desired. Additionally, the silanes may react with the organic linker (e.g., with the carboxylic acid groups on the organic linker), similar to the endcaps described above. Suitable silanes are preferably alkoxy silanes, and particularly C₁-C₄ alkoxy silanes. Exemplary silanes include those chosen from methyltrimethoxysilane, tetraethoxysilane, isobutyltrimethoxysilane, phenyltrimethoxysilane, nonafluorohexyltriethoxysilane, 2-(3,4-epoxycyclohexyl)ethyltrimethoxysilane, or combinations thereof. When a crosslinker is grafted to the MOF, it may be added in excess. It is preferably present in the reactive composition at a level of about 0.1% to about 90% by weight, more preferably about 0.25% to about 80% by weight, and even more preferably about 0.45% to about 75% by weight, based upon the total weight of the MOF taken as 100% by weight. The grafted MOF is further purified and formulated for use.

Silanes can be included in the composition in applications where a siloxane film is desired. In these instances, the silane is preferably not bonded to the MOF and does not react with the MOF during film formation but instead becomes physically interspersed with/among the MOF in the final film. Suitable silanes are preferably alkoxy silanes, and particularly C₁-C₄ alkoxy silanes. Exemplary silanes for these applications include those chosen from silanes that can be crosslinked without reacting to the MOFs such as polydimethylsiloxane (PDMS), polymethylhydrosiloxane or Poly (dimethylsiloxane-co-methylhydrosiloxane) copolymers, with terminal or branching functional groups such as vinyl and hydrosilanes cured with karstedt catalyst. When a silane is included in this embodiment, it is preferably present in the composition at a level of about 0.1% to about 500% by weight, more preferably about 0.25% to about 100% by weight, and even more preferably about 0.45% to about 75% by weight, based upon the total weight of the composition taken as 100% by weight.

In some embodiments, the composition consists essentially of, or even consists of, the MOF in a solvent system. In other embodiments, the composition consists essentially of, or even consists of, the MOF and a crosslinker in a solvent system.

In some embodiments, the composition consists essentially of, or even consists of, the MOF and a catalyst and/or a silane in a solvent system. In other embodiments, the composition consists essentially of, or even consists of, the MOF, a crosslinker, and one or both of a catalyst and/or a silane in a solvent system.

### METHODS OF USE

The MOF compositions described above can be formed into a film by applying to a substrate or other surface where a low-RI film is needed. This applying can be accomplished via any number of methods, including spin coating, dip coating, inkjet printing, roller coating, slot coating, die coating, screen printing, draw-down coating, jetting, or spray coating. One method involves spin-coating the composition at speeds of about 500 rpm to about 3,000 rpm, and preferably about 1,000 rpm to about 1,500 rpm, for a time period of about 20 seconds to about 60 seconds, and preferably about 30 seconds to about 40 seconds. Another method involves dip coating using a conventional dip-coater. Typical dipping rates vary from about 1 mm/s to about 10 mm/s.

Regardless of the application method, the applied composition is preferably heated to a temperature that is lower than the decomposition temperature of the organic linker included in the MOF. Preferably, the temperature is no higher than about 10° C. below the thermal decomposition temperature of the organic linker, more preferably no higher than about 20° C. below the thermal decomposition temperature of the organic linker, and even more preferably no higher than about 30° C. below the thermal decomposition temperature of the organic linker. In embodiments where two or more types of organic linker are utilized, the foregoing ranges are set relative to the lowest thermal decomposition temperature of the two or more types of organic linkers.

Additionally or alternatively, in embodiments including an endcap, the heating temperature is preferably lower than the thermal decomposition temperature of the endcap included in the MOF. Preferably, the temperature is no higher than about 10° C. below the thermal decomposition temperature of the endcap, more preferably no higher than about 20° C. below the thermal decomposition temperature of the endcap, and even more preferably no higher than about 30° C. below the thermal decomposition temperature of the endcap. In embodiments where two or more types of endcaps are utilized, the foregoing ranges are set relative to the lowest thermal decomposition temperature of the two or more types of endcaps.

Typical heating temperatures are about 145° C. or lower, preferably about 125° C. or lower, more preferably about 40° C. to about 125° C., and even more preferably about 60° C. to about 125° C. Typical time periods of heating are about 1 second to about 6 minutes, and more preferably about 60 seconds to about 4 minutes.

In some embodiments, heating causes crosslinking of the MOF. This crosslinking can be self-crosslinking and/or crosslinking through an added crosslinker, such as those described previously. Typically, this crosslinking would involve a group on the crosslinker (e.g., vinyl, epoxy) reacting with a group on the organic linker (e.g., —COOH). The reactive group on the organic linker is typically an end group, but it could be an internal group, such as the double-bonded carbon atoms present in the middle of a maleic acid molecule.

It is preferred that after heating, at least about 50% by weight, preferably at least about 75% by weight, more preferably at least about 90% by weight, and more preferably about 100% by weight of the total starting organic linker quantity remains (i.e., is not thermally decomposed or pyrolyzed). Additionally, or alternatively, in embodiments where an endcap is present in the MOF, at least about 50% by weight, preferably at least about 75% by weight, more preferably at least about 90% by weight, and more preferably about 100% by weight of the total starting endcap quantity remains (i.e., are not thermally decomposed or pyrolyzed) after heating.

In these embodiments, it is preferred that the formed low-RI film is substantially insoluble in typical organic solvents such as ethyl lactate, propylene glycol methyl ether acetate, propylene glycol methyl ether, propylene glycol n-propyl ether, cyclohexanone, acetone, gamma butyrolactone, or mixtures thereof. Thus, when subjected to a stripping test, the low-RI film preferably has a percent stripping of less than about 5%, more preferably less than about 1%, and even more preferably about 0%.

The percent stripping can be determined by measuring the average thickness (determined by averaging measurements taken at five different locations) of the low-RI film before the low-RI film is exposed to any developer solvents. These averaged measurements are the initial film thickness. Next, a solvent (e.g., ethyl lactate) is puddled onto the film for about 30 seconds, followed by spin drying at about 3,000 rpm for about 30 seconds to remove the solvent. The average thickness is determined again by measuring at approximately the same five locations on the wafer as the locations used to determine the initial film thickness, and the averages of these measurements is the final film thickness. The amount of stripping is the difference between the initial and final film thicknesses. The percent stripping is:

$$\% strippping = ( \frac{amount of stripping}{initial average film thickness} ) \times 100.$$

In other embodiments, the heating simply results in solvent removal. In other words, in these embodiments, no crosslinking (and preferably no other reaction) takes place during heating.

In either instance, the heating forms the final low-RI film, and that film will preferably have an average thickness (measured at five locations by ellipsometry) of about one-fourth of the wavelength of the targeted light. This typically results in thicknesses of about 50 nm to about 600 nm, preferably about 75 nm to about 450 nm, more preferably about 75 nm to about 300 nm, and even more preferably 90 nm to about 140 nm. In some embodiments, multiple application steps are carried out to achieve a thicker film.

It will be appreciated that the formed films can have a refractive index of about 1.45 or lower, preferably about 1.35 or lower, and more preferably about 1.25 or lower, even at the above thicknesses. In some embodiments, the refractive index of the film will be about 1.1 to about 1.45, preferably about 1.18 to about 1.35, and more preferably about 1.18 to about 1.25. The foregoing refractive indices can be achieved at wavelengths of about 200 nm or greater, preferably about 300 nm or greater. In some embodiments, these refractive indices are achieved at wavelengths of about 200 nm to about 1,600 nm, preferably about 300 nm to about 1,000 nm, more preferably about 300 nm to about 575 nm, and even more preferably at about 550 nm.

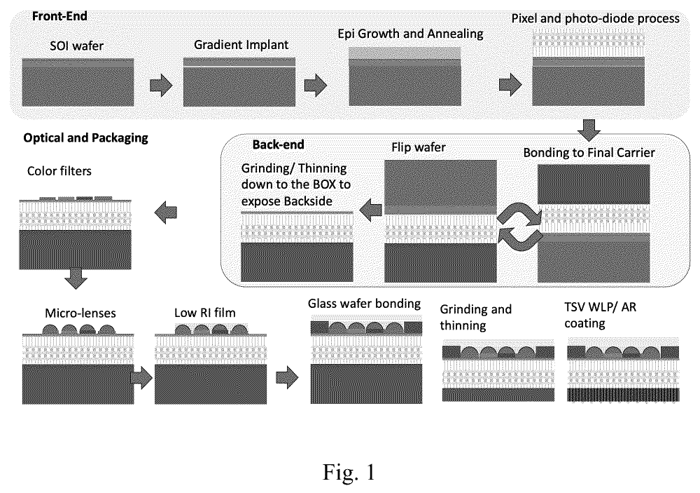

The substrate on which the low-RI film described herein can be formed includes most any substrate where that film type is needed, including in the formation of various microelectronic devices. For example, FIG. 1 shows a schematic diagram of using the low-RI films in a back side illumination CMOS image sensor. The films can also be used as a gap fill material, in color filters, between photodiodes, for waveguide applications, conformally on a microlens, and on cover as an antireflective coating. Thus, the substrate can be glass, polycarbonate, one or more micro lenses, a lens body, patterned substrates, silicon nitride, or high RI substrates (e.g., RI about 1.6 or higher).

Additional advantages of the various embodiments will be apparent to those skilled in the art upon review of the disclosure herein and the working examples below. It will be appreciated that the various embodiments described herein are not necessarily mutually exclusive unless otherwise indicated herein. For example, a feature described or depicted in one embodiment may also be included in other embodiments but is not necessarily included. Thus, the present disclosure encompasses a variety of combinations and/or integrations of the specific embodiments described herein.

As used herein, the phrase “and/or,” when used in a list of two or more items, means that any one of the listed items can be employed by itself or any combination of two or more of the listed items can be employed. For example, if a composition is described as containing or excluding components A, B, and/or C, the composition can contain or exclude A alone; B alone; C alone; A and B in combination; A and C in combination; B and C in combination; or A, B, and C in combination.

The present description also uses numerical ranges to quantify certain parameters relating to various embodiments. It should be understood that when numerical ranges are provided, such ranges are to be construed as providing literal support for claim limitations that only recite the lower value of the range as well as claim limitations that only recite the upper value of the range. For example, a disclosed numerical range of about 10 to about 100 provides literal support for a claim reciting “greater than about 10” (with no upper bounds) and a claim reciting “less than about 100” (with no lower bounds).

### EXAMPLES

The following examples set forth methods in accordance with the disclosure. It is to be understood, however, that these examples are provided by way of illustration, and nothing therein should be taken as a limitation upon the overall scope.

### Example 1

### Synthesis and Purification of UiO-66 Clusters

To a 100 ml round bottom flask, 217 mg of zirconium dichloride oxide octahydrate (AK Scientific, Inc., CA) were added. Then 28.7 g of N,N-Dimethylformamide (DMF) (TCI America Inc., OR) were added. This mixture was sonicated for 5 mins on ice water until clear. To a 50 ml centrifuge tube, 0.4441 g trifluoroacetic acid (TCI America Inc., OR), 0.5070 g of terephthalic acid (Sigma-Aldrich Inc.), and 9.87 g of DMF (TCI America Inc., OR) were added. This was sonicated until clear and then added to the flask, which was then loosely capped with a cork stopper. The reagents were mixed while the bottom of the flask was immersed in a heated oil bath heated from room temperature to 90° C. The mixture was heated at 90° C. for another 836 mins after the oil bath reached 90° C. and then allowed to cool to room temperature.

After cooling, 20 g of hexanes (Fisher Scientific Company) and 20 g of acetone (FUJIFILM Wako Chemicals U.S.A., Inc.) were added to the flask and mixed thoroughly by agitating using a pipette. The contents were transferred into 50 ml centrifuge tubes. Then the contents were allowed to settle for 20 mins. This mixture was centrifuged at 4,500 rpm for 5 mins and decanted. Then 13 g of methanol (Sigma-Aldrich Inc.) were added to the solids, which were re-suspended using a pipette. This mixture was sonicated in the centrifuge tubes in ice water for 5 mins. The contents of the tubes were then transferred into a 500 ml tripour. This was followed by addition of 5 g of hexanes and 1 g of acetone to the tripour and mixed using a pipette. After this an additional 5.2 g of hexanes and 1.5 g of acetone (FUJIFILM Wako Chemicals U.S.A., Inc.) were added to the tripour. Precipitates became visible after 5 minutes of standing. This mixture was centrifuged for 5 mins at 4,500 rpm. The liquid was decanted, and the solids were re-dispersed in 13 g of methanol and sonicated in ice water for 15 mins. This solution was stored at −20° C. over 5 days.

### Example 2

### Dip Coating and UV-Vis % Transmittance with Materials

### Synthesized in Example 1 on Polycarbonate

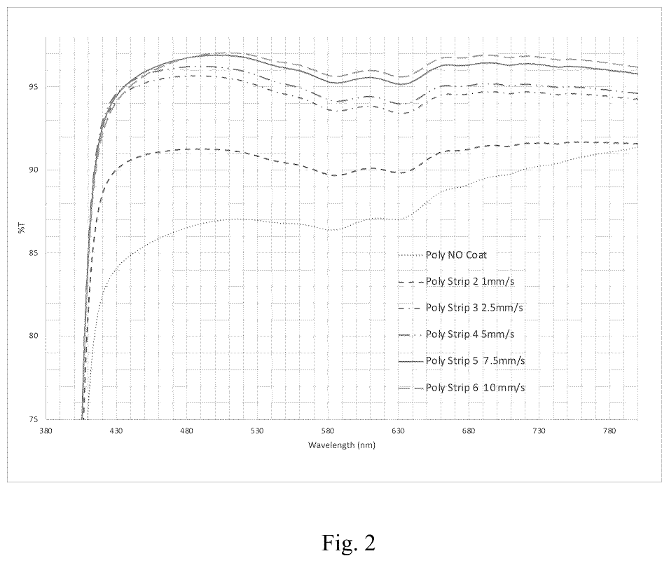

Samples of the material prepared in Example 1 were thawed at room temperature. The samples were transferred into 20 ml glass vials and sonicated for 10 mins in ice water. Right after this sonication, rectangular strips of polycarbonate substrate were dip coated in the sonicated sample materials. Different substrates were dip coated using variable movement rates: 10 mm/s; 7.5 mm/s; 5 mm/s; 2.5 mm/s; 1 mm/s; and 0.5 mm/s. The dip-coated substrates were baked in an oven at 125° C. for 2 hours. The % Transmittance (% T) of the dip coated strips was measured and compared to that of uncoated polycarbonate strips. As shown in FIG. 2, the % T of polycarbonate increased to over 96% at 550 nm for the substrates coated at 7.5 and 10 mm/s compared to the uncoated polycarbonate control at 86%.

### Example 3

### Formulation of Example 1 with Glycidyl Poss, Dip Coating, and % T Data

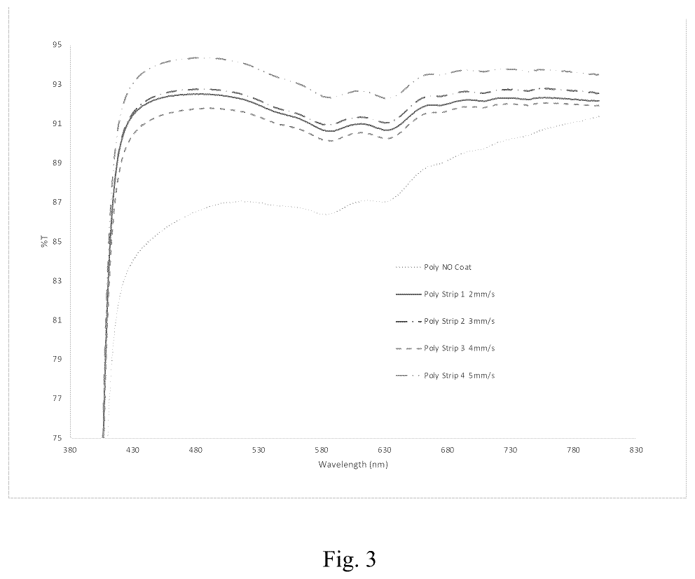

In a 20 ml vial 0.048 g of glycidyl polyhedral oligomeric silsesquioxane (GPOSS) (Hybrid Plastics, Inc.) was added. Then 9.941 g of the material from Example 1 were added. This mixture was sonicated in ice water for 5 mins. After sonication, polycarbonate strips were dip coated in the resulting material at the following rates: 2 mm/s; 3 mm/s; 4 mm/s; and 5 mm/s. After dip coating, the coated polycarbonate strips were baked in an oven at 125° C. for 2 hours. The % Transmittance (% T) was measured and compared to that of uncoated polycarbonate strips. The % T was shown to increase from 86% for uncoated strips at 550 nm to about 92% for the polycarbonate substrate dip coated at 55 mm/s. The data is presented in FIG. 3.

### Example 4

### Synthesis and Purification of UiO-66-Type Clusters with Maleic Acid and TFA

In a 250 ml round bottom flask, 412 mg of zirconium dichloride oxide octahydrate (AK Scientific, Inc., CA) was placed. To this 57.004 g of N,N-Dimethylformamide (TCI America Inc., OR) were added. This mixture was sonicated for 5 mins on ice water to dissolve. In a 50 ml centrifuge tube, 0.927 g maleic acid (Alfa Aesar), 0.9209 g trifluoroacetic acid (TCI America Inc., OR), and 1.0168 g terephthalic acid (Sigma-Aldrich Inc.) were added. Then 19.1274 g of N,N-Dimethylformamide (TCI America Inc., OR) were added. This was sonicated for 5 mins and then heated to 90° C. for 2 mins until clear.

The contents of the centrifuge tube were then added to the round bottom flask and mixed while in an oil bath heat as it was heated from room temperature. After the oil bath reached 90° C., the mixture was heated at 90° C. for an additional 836 mins while stirred at 900 rpm. The reaction was set up under nitrogen flow at 400 sccm.

Once cool, 20.98 g of acetone (FUJIFILM Wako Chemicals U.S.A., Inc.) were added to the above reaction mixture, after which 20.12 g of hexanes (Fisher Scientific Company) were added. The reaction mixture was allowed to settle. After settling, an additional 20 g of hexanes were added, and the mixture was allowed to settle again. This mixture was split into 4×50 ml centrifuge tubes followed by centrifugation for 10 mins at 4,500 rpm. The solids sediments were decanted to remove DMF and then 37.2 g of methanol (Sigma-Aldrich Inc.) were added and agitated using pressurized pipette flow followed by sonication for 5 min in ice bath and centrifuge. This yielded an opal colored translucent UiO-66-type suspension. This was centrifuged at 4,500 rpm for 10 mins. This did not centrifuge the clusters down. This mixture was split into two 1000 ml tripour containers to test different precipitation conditions. One container was diluted with 40 g hexanes, 37.2 g of methanol (Sigma-Aldrich Inc.), and 21 g acetone (FUJIFILM Wako Chemicals U.S.A., Inc.) to test for precipitation. Sedimentation was observed after 5 mins. Then the contents of the second container were combined with the first. An additional 20 g of hexanes were added followed by 5.4 g of acetone (FUJIFILM Wako Chemicals U.S.A., Inc.) and an additional 10 g of hexanes. Acetone (FUJIFILM Wako Chemicals U.S.A., Inc.) was used to collect precipitate residues and balance the tubes. At this time the clusters, which had mostly settled, were centrifuged at 4,500 rpm for 10 mins. The tubes were decanted. To the solids 30.12 g of methanol (Sigma-Aldrich Inc.) were added. This was sonicated in ice water for 15 mins. Then an additional 15 mins of sonication was performed. This yielded a solution that looked opal translucent, which was sonicated for an additional 15 mins on ice.

### Example 5

### Dip Coating and UV-Vis % Transmittance with Materials

### Synthesized in Example 4 on Treated Polycarbonate

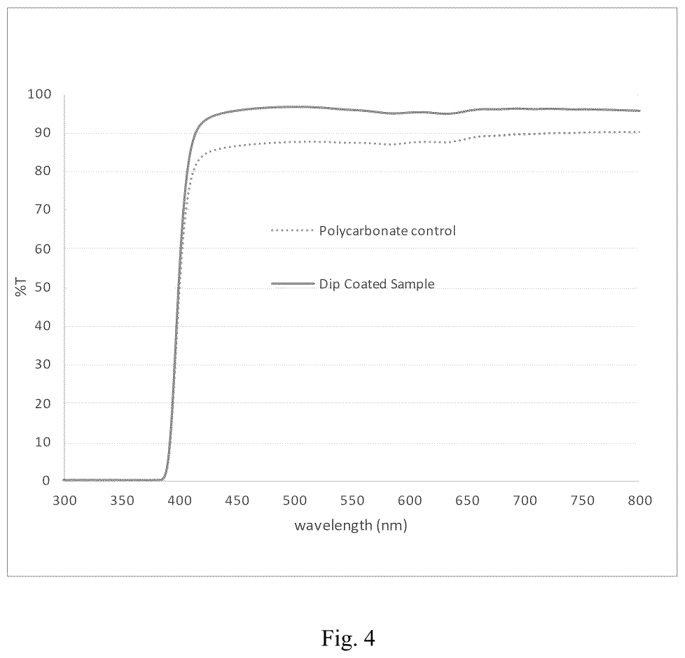

Polycarbonate substrates were soaked in 241 g of DI water, 14 g of NaOH (Sigma-Aldrich Inc.), and 4 g of Alconox (Sigma-Aldrich Inc.) and sonicated for 30 mins. The substrates were washed with lots of DI water multiple times and dried over Kimtech® Chem Wipes and in an oven for 5 mins. The base-treated polycarbonate substrates were dip coated into the solution from Example 4. The dip coating rate was about 10 mm/s. Good dip coat quality was observed on all substrates. Thickness of each coating was estimated to be around 100-130 nm based on ellipsometric thickness measurements on silicon substrates dip coated under identical settings. FIG. 4 shows the % transmittance data measured for each substrate. The % Transmittance increased to above 96% compared to untreated polycarbonate strip control.

### Example 6

### Formulation of Example 4 with Methacrylate POSS, Dip Coating, and % T Data

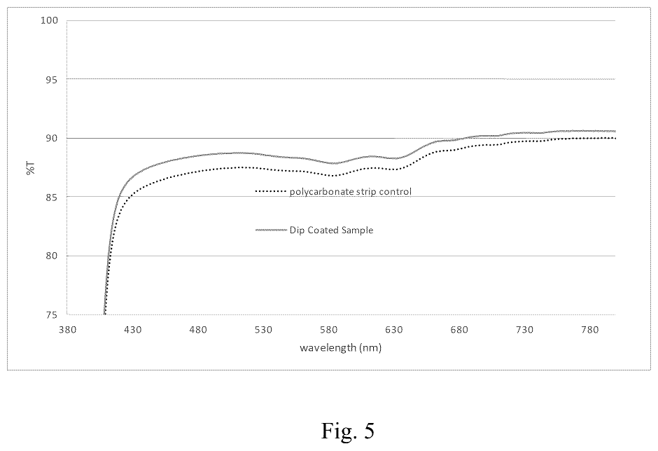

To a 20 ml glass vial 0.2501 g of methacrylate-functionalized polyhedral oligomeric silsesquioxane (MA0735) (Hybrid Plastics, Inc.) and 9.70 g of the solution obtained in Example 4 above were added. This mixture was sonicated for 10 mins in ice bath. This formulation was dip coated on untreated polycarbonate partially at 0.25 mm/s and partially at about 10 mm/s. The % T increased from 86% to 88%, as indicated in FIG. 5.

### Example 7

### Formulation of Example 4 with Glycidyl POSS, Dip Coating, and % T Data

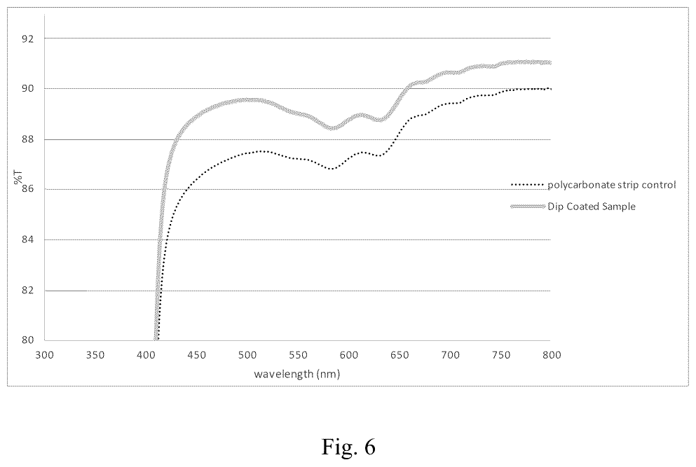

To a 20 ml glass vial 0.2633 g of glycidyl polyhedral oligomeric silsesquioxane (EP0409) (Hybrid Plastics, Inc.) and 9.99 g of the solution from Example 4 were added. This mixture was sonicated for 10 mins in ice bath. This formulation was dip coated on untreated polycarbonate partially at 0.5 mm/s and partially at about 10 mm/s. As shown in FIG. 6, the % T increased from 86% to about 88%.

### Example 8

Spin Coating with Examples 4, 6 and 7 on Silicon and Polycarbonate

The solutions obtained in Examples 4, 6, and 7 were spin coated on silicon wafers at 1,000 rpm/10K ramp followed by a bake for 5 min at 125° C. Film optics and thickness on silicon were measured for each of the resulting films. These are listed in the Table 1 below.

TABLE 1
Examples 4, 6, 7 thickness and optics after spin coating on silicon.

| Formulation | nm | n-633 |
|---|---|---|
| Example 4 | 116 | 1.22 |
| Example 6 | 162 | 1.60 |
| Example 7 | 263 | 1.56 |

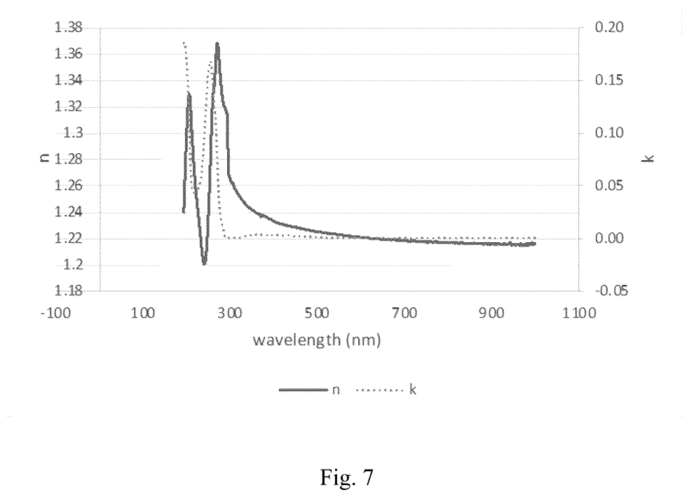

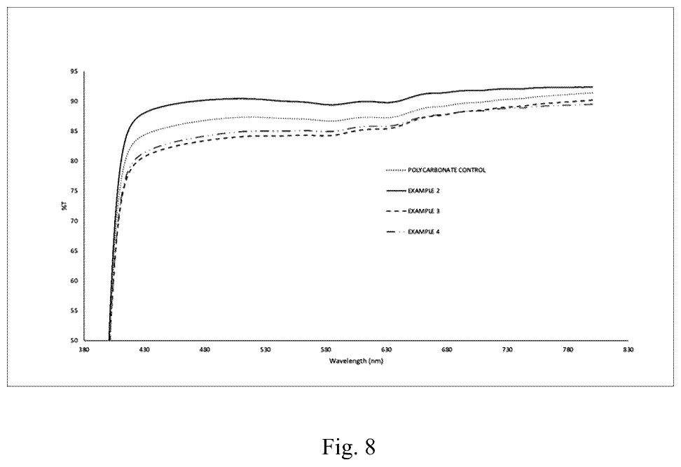

FIG. 7 shows that the n value at 550 nm for the film obtained from Example 4 was 1.22. This corresponds with a high % T of 96% on polycarbonate. The films obtained from Examples 6 and 7 (after blending with POSS chemistries) show much higher refractive indices and lower increases in % T. The % T data measured after spin coating on one side of polycarbonate wafers at about 400 rpm followed by a 2-hour bake at 125° C. is also shown in FIG. 8. The solution from Example 4 shows significant increase in % T to about 96%.

### Example 9

### Synthesis and Purification of UiO-66-Type Clusters with Maleic Acid and TFA

In a 250 ml round bottom flask, 620.2 mg zirconium dichloride oxide octahydrate (AK Scientific, Inc., CA) was weighed. To this 87.65 g of N,N-Dimethylformamide (DMF) (TCI America Inc., OR) were added. This was sonicated for 15 mins on ice water to dissolve. In a separate 50 ml centrifuge tube, 1.3919 g maleic acid (Alfa Aesar), 1.3925 g of trifluoroacetic acid (TCI America Inc., OR), and 1.5214 g terephthalic acid (Sigma-Aldrich Inc.) were added. To this 29.05 g of DMF (TCI America Inc., OR) were added. This was sonicated and heated to dissolve. The solution of acids in DMF was added to the 250 ml flask which was then placed in an oil bath at room temperature and heated until the bath reached 90° C. Then the mixture was heated at 90° C. for an additional 836 mins. After that, the reaction mixture was set up under nitrogen flow at 400 sccm. Once cool, 36 g of hexanes (Fisher Scientific Company) were added to the flask. Then about 20 ml of acetone (FUJIFILM Wako Chemicals U.S.A., Inc.) were added. To this 30 g of additional acetone (FUJIFILM Wako Chemicals U.S.A., Inc.) were added until separate phases were no longer observed. This mixture was then allowed to sit undisturbed for about one hour, at which time 15 g of hexanes and 15 g of acetone (FUJIFILM Wako Chemicals U.S.A., Inc.) were added further. This reaction mixture was transferred from the 250-ml round bottom flask to a 1000 ml tripour. The solids started settling after standing for a few minutes. This mixture was then centrifuged and decanted. About 27 g of methanol (Sigma-Aldrich Inc.) were added to the decanted solids in a pipette sonicated in ice water for 5 mins to redisperse the solids. This mixture was then centrifuged for 10 mins at 4,500 rpm at which time the supernatant was not clear. This mixture was centrifuged for an additional 30 mins at 4,500 rpm. This did not settle the clusters completely. To each centrifuge tube 6 to 8 g of hexanes were added and the resulting mixture was centrifuged at 4,500 rpm for an additional 30 mins. At this stage, the solids were collected after decanting. The solids had a translucent monolithic appearance.

To the collected decanted liquid, more hexanes were added to precipitate out the remaining clusters. The hexanes were added until phase separation was observed. This required about 49.5 g of hexanes. This was mixed by swirling a pipette and allowed to stand for 5 min. Then 20 g of acetone (FUJIFILM Wako Chemicals U.S.A., Inc.) were added until phase separation was no longer observed upon mixing and settling. Precipitates were clearly visible after 5 mins of standing. This mixture was transferred into 50 ml centrifuge tubes again and centrifuged for 30 mins at 4,500 rpm. Solids were collected by decanting. Remaining amounts of decanted liquid were centrifuged for 5 mins at 4,500 rpm, at which point solids were again decanted.

In a 50 ml centrifuge tube, 0.225 g of maleic acid (Alfa Aesar) was added to the solids in 40 g of methanol (Sigma-Aldrich Inc.) The solids were dispersed in this solution by using a pipette multiple times to break up clumps. All solid fractions were combined into a single centrifuge tube as noted below by combining washings. This material was sonicated for 30 mins in an ice bath. After 30 mins the solution looked translucent to clear. This mixture was then sonicated for an additional 15 mins with more ice. Samples were stored in a freezer for 5 days. The samples were then thawed at room temperature and transferred into glass vials, which were sonicated for 10 mins in an ice bath. The solution had a higher transparency at this time.

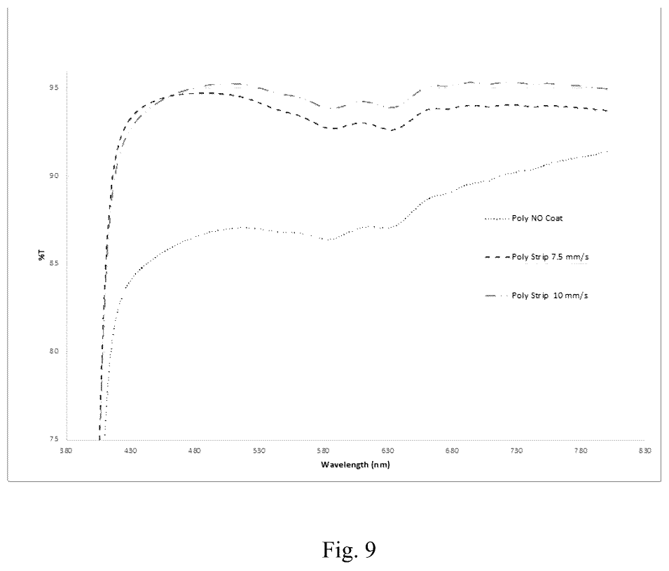

Dip coating was carried out with this formulation on 1×5 cm strips of polycarbonate at movement rates of 7.5 mm/s and 10 mm/s and baked for 2 hours at 125 C. The % T was then measured on a UV-Vis spectrometer (Agilent Cary 5000). The data are presented in FIG. 9. The % T increased to above 93% relative to 87% an un-coated polycarbonate control strip at 550 nm.

### Example 10

### Formulation of Example 9 with MA POSS, Dip Coating, and % T Data

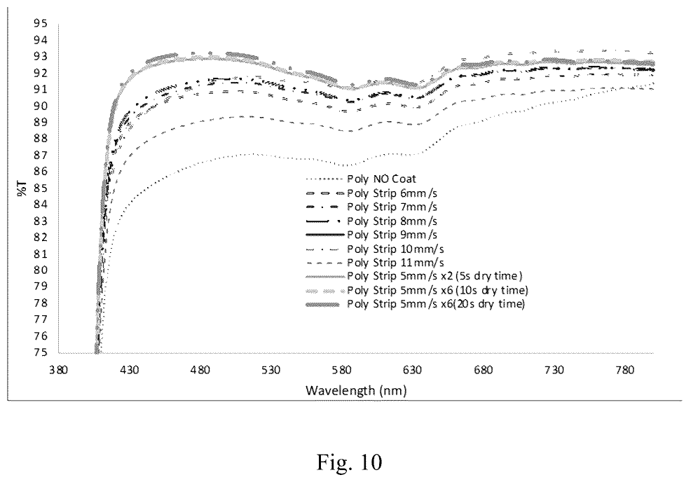

In a 20 ml glass vial 0.051 g of MA-POSS (Hybrid Plastics, Inc.) and 9.95 g of the solution obtained in Example 9 were placed and sonicated in ice water for 5 mins. The resulting material was dip coated on polycarbonate substrates using the following movement rates and repetitions, if indicated: 6 mm/s; 7 mm/s; 8 mm/s; 9 mm/s; 10 mm/s; 11 mm/s; 15 mm/s; twice at 5 mm/s with 5 s dry time; 6 times at 5 mm/s with 10 s dry time; and 6 times at 5 mm/s with 20 s dry time. The coated substrates were cured in oven for 2 hours at 125 C. Multi-coats at 5 mm/s showed the highest % T 92% vs. un-coated polycarbonate control at 87% at 550 nm as shown in FIG. 10.

### Example 11

### Formulation of Example 9 with Divinylbenzene, Dip Coating, and % T Data

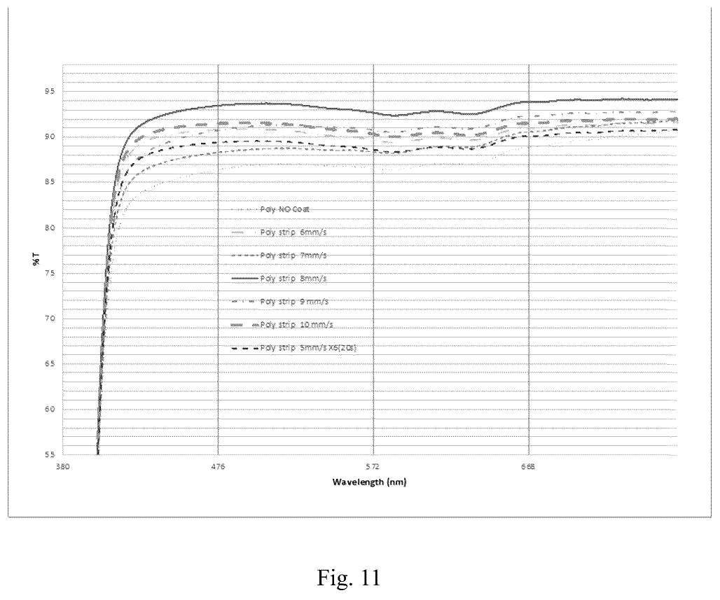

In a 20 ml glass vial, 0.05 g of Divinylbenzene (DVB) (TCI America Inc., OR) and 9.95 g of the solution from Example 9 were added and sonicated in ice water for 5 mins. The resulting material was dip coated on polycarbonate substrates at the following movement rates and repetitions, where indicated: 6 mm/s; 7 mm/s; 8 mm/s; 9 mm/s; 10 mm/s; 11 mm/s; 15 mm/s; 2× at 5 mm/s with 5 s dry time; 6× at 5 mm/s with 10 s dry time; and 6× at 5 mm/s with 20 s dry time. The coated substrates were cured in an oven at 125 C for 2 hours. Film coated on polycarbonate 6 times at 5 mm/s with 20 s dry time passed 2 H but failed 3 H pencil hardness. The results are displayed in FIG. 11.

### Example 12

### Room Temperature Aging of Materials

The materials described in Examples 1 and 3 experienced some gelling at room temperature after standing for about 20 hours. The material from Example 1 could not be redispersed by sonication after 15 mins in ice bath. The material from Example 1 had some transparency restored after gelling but was hazy after sonication. The maleic-acid-derivatized UiO-66-type formulations described in Examples 9, 10, and 11 had some sediment but were free flowing without sonication. The Example 1 material was redispersed back into solution by sonication for 15 mins in ice bath.

### Example 13

### Synthesis and Purification of UiO-66-Type Clusters with Maleic Acid, TFA, and Functionalized with Glycidyl Methacrylate

In a 500-g glass bottle with cap, 223 mg biphenyl dicarboxylic acid (BCD) (TCI America Inc., OR), 1.3653 g of terephthalic acid (Sigma-Aldrich, Inc.), and 42.5 g of N,N-Dimethylformamide (TCI America Inc., OR) were added followed by 1.44 g of maleic acid (Alfa Aesar) and 1.15 g of trifluoroacetic acid (TCI America Inc., OR). The bottle was capped until the smoke subsided. The mixture was heated at 90° C. in oil bath to dissolve. This solution was then filtered through a 1 um filter to remove any undissolved clusters. In a separate clean oven dried 250 ml round bottom flask, 623 mg of Zirconyl chloride oxide octahydrate (AK scientific) were added followed by 81 g of N,N-Dimethylformamide (TCI America Inc., OR) and this was mixed until clear. A stir bar was added to the round bottom flask. The acid solutions were added at room temperature to the round bottom flask containing the zirconyl chloride at which time the oil bath was heated. After the oil bath reached 90° C., the round bottom flask was immersed in the oil and the mixture was heated at 90° C. for 300 mins under nitrogen flow at 400 sccm with stirring at 900 rpm. The reaction flask was capped with nitrogen flow connected with bubbler.

To the reaction mixture 11 ml of glycidyl methacrylate (GMA) were added and the mixture was stirred at 900 rpm at room temperature for 2 hours. After mixing for 2 hours, the reaction mixture was poured out into 200 ml of hexanes and then 200 ml of acetone were added to this mixture until there was no observable interface. The mixture was then allowed to settle and then centrifuged at 4,500 rpm for 30 s. The precipitate pellet was then suspended in 20 ml of ethanol. This was precipitated again in 100 ml of hexanes and 100 ml of acetone. The precipitate solids were centrifuged at 1,500 rpm for 60 s. The precipitates were then centrifuged for 30 seconds at 4,500 rpm. The solids were then re-suspended in 40 ml of ethanol and sonicated in ice bath for 60 minutes. This was stored in the freezer at −20C. The following day, the above solution was sonicated for 30 mins followed by an additional 30 mins while monitoring the temperature to make sure it did not exceed 20° C. The solution was not completely clear at that point. The solution was then centrifuged at 4,500 rpm for 60 seconds. The solids were collected. The remaining liquid was centrifuged further at 4,500 rpm for 10 mins. No significant solids were collected in this liquid. The liquid ethanol was saved for reformulation.

### Example 14

### Testing of Example 13 Formulation

In a 20-ml glass vial, 2 g of the above solution in ethanol saved at the end of Example 13 was mixed with 0.16 g of dimethylsulfoxide (DMSO) (Sigma-Aldrich Inc.). This was sonicated for 1 min at which point the solution was nearly clear. Then the resulting solution was coated three times on a silicon substrate and baked as described in Table 2 below:

TABLE 2

| | Spin Speed, | Bake Temp., Bake | Thickness | | |
|---|---|---|---|---|---|
| Cycle | Spin Time | Time | (nm) | n@1400 nm | n@550 nm |
| 1 | 1,500 rpm, | 125° C., 5 min | 212 | 1.20 | 1.22 |
| | 60 sec | 260° C., 15 min | | | |
| 2 | 1,500 rpm, | 125° C., 5 min | | | |
| | 60 sec | | | | |
| 3 | 1,500 rpm, | 125° C., 5 min | | | |
| | 60 sec | | | | |

| | | | | |
|---|---|---|---|---|
| Final Bake | 260° C., 15 min | 175 | 1.20 | 1.22 |

The refractive indices of the films did not change through bake at 260° C. The films shrank 17% after bake at 125° C. and at 260° C.

### Example 15

### Formulation of Glycidyl Methacrylate Functionalized UiO-66-Type Clusters in DMSO/Ethanol Mixtures

In this Example, 4.2 g of dimethylsulfoxide (Sigma-Aldrich Inc.) were added to the solids collected in Example 13 above after which about 30 ml of ethanol were added followed by sonication for 30 mins. Then the resulting material sat at room temperature overnight. At this point, the solution looked mostly clear. This formulation was filtered using 6-micron filter paper to high clarity.

### Example 16

### Tests with the Formulation from Example 15

Three samples of the formulation obtained from Example 15 above were prepared. One of the samples was further filtered through a 1-micron filter. The three samples were spin coated, baked, and processed as noted in Table 3 below:

TABLE 3

| Material | Process | Thickness | n@1400 nm | n@550 nm |
|---|---|---|---|---|
| 6-micron | On Silicon wafer, | 142 nm | ~1.21 | ~1.22 |
| filtered | 1,500 rpm 30 s, | | | |
| | 125° C. 5 m | | | |
| 6-micron | Coated on silicon | 572 nm | ~1.22 | ~1.23 |
| filtered | wafer 4 times as | | | |
| | follows: 1,500 rpm | | | |
| | 30 s, 125° C. 5 m | | | |
| 1-micron | On Si Reference, | 158 nm | ~1.20 | ~1.22 |
| filtered | 1,500 rpm 30 s, | | | |
| after 6-um | 125° C. 5 m | | | |
| filtration | | | | |

The spin coating process and the corresponding thicknesses indicate the films were cross-linked and that the thickness of the films can be built up to at least 572 nm through 4 coat-bake cycles. Furthermore, the refractive index of the films at short and long wavelengths remained low (below 1.25) after multiple coat and bake cycles, making the material ideal for use as an ultra-low refractive index material for optical applications in visible, IR, and ranges beyond.

### Example 17

### Synthesis and Purification of UiO-66-Type with MTMS/TEOS

A hotplate was preheated to 90° C. to begin. To a dry 500 mL round bottom flask with a stir bar, 1.438 g of terephthalic acid (TCI America Inc., OR) and 161.38 g of N,N-Dimethylformamide (DMF) (TCI America Inc., OR) were added. This mixture was stirred at 90° C. until dissolved.

In a scintillation vial, 2.5 g of trifluoroacetic acid (TFA) (Sigma-Aldrich, Inc.) were added. Once the solution in the flask was fully dissolved, the TFA was added. In a separate vessel with a stir bar, 1.2569 g of ZrOCl₂ (AK Scientific, Inc., CA) and 40 g of DMF (TCI America Inc., OR) were added. This mixture was stirred at room temperature until dissolved. The reaction mixture was heated at 90° C., stirred at 400 rpm, and kept under nitrogen flow for 4 hours. After 4 hours, the heat was turned off and the mixture was allowed to cool to room temperature. The stirring and nitrogen flow were maintained overnight. The solution was then placed in the freezer at −20° C.

The reaction mixture was taken from the freezer and sonicated to clarity before being used. Once clear, the mixture was added to a new 1 L Aicello bottle on a weigh plate. The weight of the mixture was around 200 grams. Next, 10 g of methyltrimethoxysilane (MTMS, actual 10.25 g) and 3 g of tetraethoxysilane (TEOS, actual 3.05 g) were added. The bottle was capped and shaken vigorously to mix. At this point, the pH of the solution was measured using a piece of pH paper to be about 4. Next, 20 g of a 0.1N nitric acid solution (HNO₃, actual 20.24 g) was added to the mixture. The bottle was once again capped and vigorously shaken to mix. The pH of the solution was then measured to be about 2.

This mixture (still in the 1 L Aicello bottle) was attached to a tumbler and was allowed to rotate constantly overnight. The following day, the reaction mixture was slightly hazy. In a 250 g tripour, 20 g of hexanes (Fisher Scientific Company) then 20 g of acetone were added. No precipitates were observed. Then an additional 20 g of hexanes and 20 g of acetone were added. This was followed by addition of an additional 50 g of hexanes and 50 g acetone. This mixture was transferred into the reaction Aicello bottle and allowed to sit for 1 hour. Hexane layers had separated so an additional 150 ml of acetone were added until no more layers were observed followed by agitation of the bottle. After this, isolation of particles by centrifugation was carried out at 4,500 rpm for 1 min. This did not yield much precipitate. An additional 75 ml of hexanes and 90 ml of acetone were added. After waiting 5 minutes, two tubes were centrifuged at 4,500 rpm. This improved the yield considerably. An additional 100 ml of acetone were added to the mixture after decanting centrifuged tubes to remove phase separation of hexanes. This was allowed to sit for 5 mins. This clearly formed precipitates that were visibly phase separated. This was centrifuged at 4,500 rpm for 1 min until all the particles were isolated. The pellets from the centrifugation were resuspended in 200 ml of reagent alcohol using a pipette. This was followed by centrifuging for 2 mins at 4,500 rpm. Some haze was still present in the reagent alcohol. This supernatant was collected separately, and 70 ml of hexanes were added to the mixture. After 5 mins there were substantial precipitates which were readily isolated by centrifugation at 4,500 rpm for 1 min. After waiting an additional 1 min, more precipitates formed which were recovered through additional centrifugation. The centrifuged pellets were collected in 4 50 ml centrifuge tubes.

To each tube about 10 ml of PGME were added followed by sonication for 1 hour in an ice bath. The tubes were stored overnight at −20° C. To one of the tubes, 0.5998 g of 5% R30N surfactant (Megaface/DIC) in PGME was added. To this formulation 1 g of PGMEA and 2 grams of DMSO were added. These formulations were nearly clear and were spin coated on AMTI chips, as noted in Table 4 below.

TABLE 4

| | | | Total | | |
|---|---|---|---|---|---|
| | | Bake Temp., Bake | Thickness | n@1400 | n@550 |
| Cycle | Spin Speed, Spin Time | Time | (nm) | nm | nm |
| 1 | 1,000 rpm, 60 sec | 240° C., 1 min | 468 | 1.24 | 1.26 |
| 2 | 1,000 rpm, 60 sec | 240° C., 1 min | | | |
| 3 | 1,000 rpm, 60 sec | 240° C., 1 min | | | |
| 4 | 1,000 rpm, 60 sec | 240° C., 1 min | | | |
| 5 | 1,000 rpm, 60 sec | 240° C., 2 min | | | |

| | | | | |
|---|---|---|---|---|
| Final Bake | 260° C., 15 min | 415 | 1.25 | 1.27 |

The optics of the films did not change after baking at 260° C. for 15 mins. The film shrank about 11% between 240° C. and 260° C. bakes.

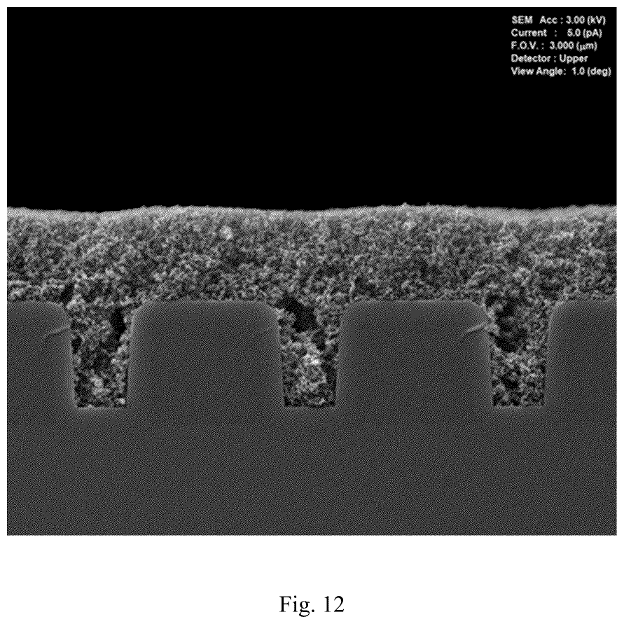

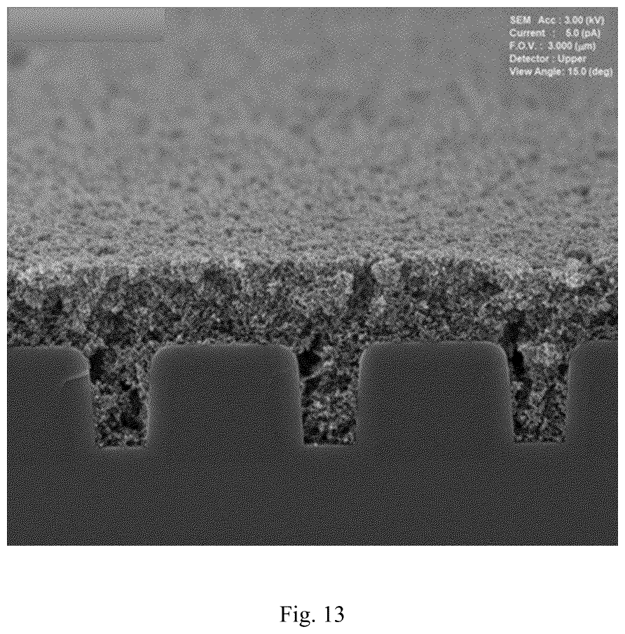

The films show good gap fill performance as shown in FIGS. 12 and 13.

### Example 18

### Synthesis and Purification of UiO-66-Type with 9-ACA

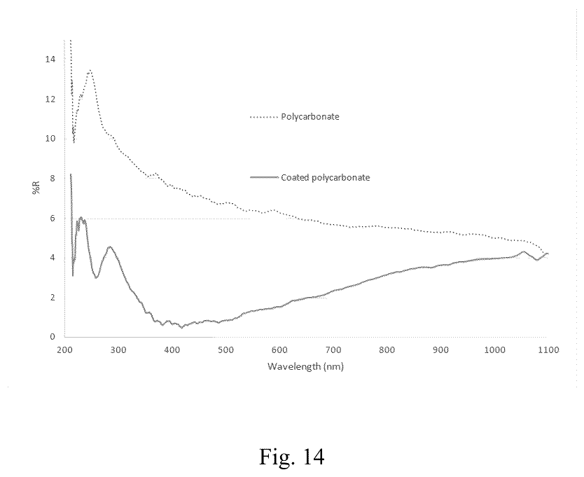

In a 3-neck flask, 1.43 g of terephthalic acid (TCI America Inc., OR), 4.04 g of 9-anthracene carboxylic acid (9-ACA) (Midori Kagaku Co., Ltd.) and 160.05 g of DMF (TCI America Inc., OR). This mixture was capped with a septum and heated to 90° C. for 10 mins. To this clear mixture 2.43 g of trifluoroacetic acid (TFA) (Sigma-Aldrich Inc.) were added. In a separate 250 ml glass bottle, 1.259 g of zirconyl chloride (AK scientific) and 40.03 g DMF were added. This mixture was dissolved by swirling. Once dissolved, the terephthalic acid solution was added to the Zirconium solution and immersed into an oil bath at 90° C. for 240 mins and stirred at 400 rpm. After the mixture cooled to room temperature, it was precipitated by addition of the reaction mixture into 75 ml of hexanes and 90 ml of acetone and swirling. Once the precipitates were visible, precipitate mixtures were centrifuged at 4,500 rpm for 3 mins. The precipitate pellets were then resuspended in 15 ml of reagent alcohol. Then centrifuged again for 3 mins at 4,500 rpm. The collected pellet was then resuspended in 2.5 g of DMSO and 10 g of PGME and sonicated for a total of 90 mins in an ice bath. This formulation was spin coated at 2,500 rpm followed by a 125° C. bake for 3 mins on a silicon wafer. The thickness of the film was measured to be 105 nm by ellipsometry. The formulation was identically spin-coated on polycarbonate followed by 125° C. bake for 12 hours. Precent reflectivity on the polycarbonate substrate was evaluated using an F-40 instrument. This data is shown in FIG. 14.

### Example 19

### Synthesis and Purification of UiO-66-Type Particles with Maleic Acid, TFA, and Functionalized with Glycidyl Methacrylate

In a 500 ml 3-neck round bottom flask we weigh 230.1 mg of Biphenyl dicarboxylic acid (TCI America Inc., OR), 1.3672 g of Terephthalic acid (TCI America Inc., OR) are added. To the above mixture, 1.42 g of maleic acid (Alfa Aesar) were added. Then 80.41 g of DMF (TCI America Inc., OR) were added followed by 1.22 g Trifluoroacetic acid (TFA) (TCI America Inc., OR). Smoke was then observed. The bottle was capped with a septum until the smoke subsided. The solution was then heated to 90° C. for 20 mins. In a 250 ml clear glass bottle 620.4 mg of Zirconyl chloride oxide octahydrate (AK scientific) were added and to this 40 g of DMF (TCI America Inc., OR) were added and this was mixed until clear. This solution was then added to the round bottom flask. After the oil bath reached 90° C., the round bottom flask was immersed into the bath and heated for 270 mins. The reaction was performed under nitrogen flow at 400 sccm and with 900 rpm stirring.

The reaction was stopped after 270 mins. It was then left at room temperature overnight while stirring under nitrogen. The solution appeared hazy (pale white opal) at this stage. After about 24 hours, Glycidyl methacrylate (Sigma-Aldrich Inc.) 10 ml were added, and the reaction mixture was stirred at 900 rpm for 2 hours at room temperature. The solution was precipitated by adding 100 ml hexanes and 100 ml acetone mixtures. The precipitate solution was centrifuged for 1 min at 4,500 rpm. The solids collected were redispersed in 19 g of ethanol. The suspension was precipitated again in 50ml of hexanes and 50 ml acetone and centrifuged to collect solids again after 1 min at 4,500 rpm. Then the solids were again resuspended in 19 g of ethanol and sonicated in ice for 30 mins and no more. The solution was sonicated in further time batches of 30 mins while monitoring the low temperature of the ice bath.

### Example 20

### Synthesis and Purification of UiO-66-Type Particles with Maleic Acid, TFA, and Functionalized with Glycidyl Methacrylate and Butyl Glycidyl Ether

In a 50 ml centrifuge tube, 10 g of glycidyl butyl ether (Sigma-Aldrich Inc.) and 10 g of the formulation from Example 19 were added. This was sonicated for about 10 min at 20-32° C. The solution looked a bit turbid. This solution was centrifuged at 4,500 rpm for 1 min to collect solids. The solids were then dispersed in 19 g of IPA and centrifuged again to collect solids at 4,500 rpm for 1 min.

### Example 21

### Formulation of Example 20 (BSI.O23044B)

The IPA solution remaining from Example 20 was centrifuged at 4,500 rpm for 1 min to collect solids. To these solids, 2 g of DMSO were added, and the solids were dispersed using a pipette. Next, 19 g of IPA were added, and the mixture was redispersed using a pipette. The dispersed solution was then sonicated in an ice bath for 30 mins. This solution was nearly clear.

### Example 22

### Synthesis and Purification of UiO-66-Type Particles with TFA and Functionalized with 9-Anthracene Carboxylic Acid

In a 500 mL 3-neck round bottom flask, 1.43 g of Terephthalic acid (TCI America Inc., OR) and 4.05 g of 9-ACA (Midori Kagaku Co., Ltd.) were added. To this mixture, 162.5 g of DMF (TCI America Inc., OR) were added. This solution was stirred at 90° C. until the solids were dissolved. To the mixture, 2.29 g of trifluoroacetic acid (Sigma-Aldrich Inc.) were added. In a separate 250 mL 1-neck round bottom flask, 1.3104 g of Zirconyl Chloride Oxide Octahydrate (AK scientific) and 84.54 g of DMF (TCI America Inc., OR) were added. This solution was stirred at room temperature until dissolved. This mixture was then added to the 500 mL round bottom flask containing the terephthalic acid solution. The reaction mixture was stirred at 400 rpm for 240 minutes at 90° C. under light nitrogen flow. Upon addition of the reactants, the solution was clear and slightly yellow. The reaction was stopped after 240 minutes by allowing the mixture to come to room temperature. The mixture was stirred under nitrogen flow overnight.

To the above mixture, 90 mL of hexanes were added, and the mixture was vigorously shaken until a phase separation was observed in the flask. Next, 110 mL of acetone were added, and the mixture was vigorously shaken until the phase separation was no longer present. This mixture was evenly distributed among 10 centrifuge tubes and each tube was centrifuged at 4,500 rpm for 30 seconds. The supernatant was still hazy, so the tubes were centrifuged again at 4,500 rpm for 30 seconds. Despite the supernatant still being hazy it was decanted off and discarded. To each pellet, 12.5 mL of reagent alcohol were added, and each tube was centrifuged again at 4,500 rpm for 30 seconds. The supernatant was clear this time and was decanted and discarded. Each tube had about 5 mL of solid material pelleted at the bottom. Two pellets were combined into one tube using PGME to wash the solids into another tube. To the tube containing 2 pellets, 10 g of PGME and 2.5 g of DMSO were added. The tubes were sonicated on ice for 2 hours and the solution was clear. Because of the clarity of the solution, the rest of the pellets were added to this tube as well and the resulting mixture was sonicated on ice for an additional 2 hours. The resulting solution was mostly clear-the level of clarity was on par with other solutions formulated despite the increased amount of material present in the tube.

### Example 23

### Spin-Coat Analysis and Optical Property Measurement of the Solution Described in Example 22

An aliquot of the solution described in Example 22 (9-ACA-based, UiO-66-type MOF) was taken for spin-coat analysis and optical measurement. The rest of the solution was gravity-filtered through a 20-micron Whatman filter, and this filtered solution was taken alongside the unfiltered aliquot for spin-coat and optical measurement. Each solution was spun on a virgin silicon wafer at 1,000 rpm for 30 seconds. Each wafer was then baked at 125° C. for 3 minutes to remove any residual solvent. Optical properties were then measured on each wafer using a M-2000 ellipsometer. A build test was also performed using the unfiltered solution to observe how the coating's physical and optical properties were affected when multiple layers of the solution are deposited. The results are tabulated in Table 5 below.

TABLE 5

| Solution | Process | Thickness | n @ 380 nm | n @ 633 nm | n @ 1680 nm |
|---|---|---|---|---|---|
| Unfiltered | 1,000 rpm for | 217.5 nm | 1.313 | 1.280 | 1.261 |
| | 30 seconds, | | | | |
| | 125° C. bake for | | | | |
| | 3 min | | | | |
| Filtered | 1,000 rpm for | 232.0 nm | 1.316 | 1.281 | 1.266 |
| | 30 seconds, | | | | |
| | 125° C. bake for | | | | |
| | 3 min | | | | |
| Unfiltered | Each layer: | Layer 1: | Layer 1: 1.312 | Layer 1: 1.278 | Layer 1: 1.258 |
| Build Test | 1,000 rpm for | 227.0 nm | Layer 2: | Layer 2: | Layer 2: |
| | 30 seconds, | Layer 2: | 1.308 | 1.276 | 1.256 |
| | 125° C. bake for | 456.7 nm | | | |
| | 3 min | | | | |

The results show that the material can build upon itself quite well without sacrificing the refractive index. The second layer deposited an additional 229.7 nm of material onto the wafer and the refractive indices measured are well within the normal error of the machine, showing that the optical properties do not change with thickness.

### Example 24

### Synthesis and Purification of UiO-66-Type Particles with TFA and Functionalized with Oleic Acid

To a 500 mL 3-neck round bottom flask 0.7143 g of Terephthalic acid (TCI America Inc., OR) and 2.9805 g of Oleic acid (Sigma-Aldrich Inc.) were added. To this mixture, 45 g of DMF (TCI America Inc., OR) were added. This solution was stirred at 90° C. until the solids were dissolved. To the mixture, 1.21 g of trifluoroacetic acid (Sigma-Aldrich, Inc.) were added, which produced a white smoke. The solution was capped under light nitrogen flow until the smoke dissipated. In a separate 250 mL 1-neck round bottom flask, 0.6433 g of Zirconyl Chloride Oxide Octahydrate (AK scientific) and 60 g of DMF (TCI America Inc., OR) were added. This solution was stirred at room temperature until dissolved. This mixture was then added to the 500 mL round bottom flask containing the terephthalic acid solution. The reaction mixture was stirred at 400 rpm for 240 minutes at 90° C. The reaction was also kept under light nitrogen flow for the entire duration, bubbles were observed coming out of the bubbler. Upon addition of the reactants, the solution was clear. The reaction was stopped after 240 minutes by allowing the mixture to come to room temperature. The mixture was stirred under nitrogen flow overnight. The solution was observed to be more turbid and off-white after reacting (the mixture was more translucent than transparent). The stirring was stopped, and the mixture was removed from the nitrogen flow.

To the above mixture, 30 mL of hexanes were added, and the mixture was vigorously shaken until a phase separation was observed in the flask. Next, 10 mL of acetone were added, and the mixture was vigorously shaken until the phase separation was no longer present. This mixture was evenly distributed among 4 centrifuge tubes and each tube was spun at 4,500 rpm for 2 minutes. The supernatant was still hazy, so the tubes were centrifuged again at 4,500 rpm for 2 minutes. Despite the supernatant still being hazy, it was decanted off and discarded. To each pellet, 12.5 mL of reagent alcohol were added, and each tube was spun once again at 4,500 rpm for 30 seconds. The supernatant was slightly hazy, but despite this it was decanted off and discarded as before. Each tube had slightly less than 5 mL of solid material pelleted at the bottom. All the pellets were combined into one tube using PGME to wash the solids into one tube. To this tube, 20 g of PGME and 4 g of DMSO were added. This tube was sonicated under ice for 1.5 hours and the solution was observed to be clear.

This formulation was spin coated at 1,000 rpm for 60 s and baked at 205° C. for 3 minutes. A film with good coat quality and with a thickness of 120 nm and a refractive index of about 1.25 at 550 nm was obtained.

### Example 25

### Synthesis of TEOS Solgel

In this Example, 141.4 g of PGME and 41.73 g of TEOS were added to a round bottom reaction flask. Next, 35.98 g of 0.01N nitric acid was added dropwise and allowed to hydrolyze for 1 hour. The mixture was then heated at 90° C. for 2 hours with nitrogen flow through a drying column. The molecular weight of the solgel polymer was measured to be 950 Da by GPC.

### Example 26

### Formulation of TEOS Solgel

In this Example, 14.6 g of the TEOS solgel from Example 25, 165.49 g of PGME, and 19.91 g of DI water were mixed in a 100-ml Aicello bottle to prepare the formulation.

### Example 27

### Synthesis and Purification of UiO-66-Type Particles with TFA and Functionalized with 9-Anthracene Carboxylic Acid and Formulation with Example 26

To a 500 mL 3-neck round bottom flask, 1.44 g of terephthalic acid (TCI America Inc., OR) and 4.08 g of 9-ACA (Midori Kagaku Co., Ltd.) were added. To this mixture, 160.12 g of DMF (TCI America Inc., OR) were added. This solution was stirred at 90° C. until the solids were dissolved, after which 2.33 g of trifluoroacetic acid (Sigma-Aldrich Inc.) were added. In a separate 250-mL, 1-neck round bottom flask, 1.2658 g of zirconyl chloride oxide octahydrate (AK scientific) and 40.05 g of DMF (TCI America Inc., OR) were added. This solution was stirred at room temperature until dissolved. This mixture was then added to the 500-mL round bottom flask containing the terephthalic acid solution. The reaction mixture was stirred at 400 rpm for 240 minutes at 90° C. under light nitrogen flow. Upon addition of the reactants, the solution was clear and slightly yellow. The reaction was stopped after 240 minutes by allowing the mixture to come to room temperature. The mixture was stirred under nitrogen flow overnight.

To the above mixture, 90 mL of hexanes were added, and the mixture was vigorously shaken until a phase separation was observed in the flask. Next, 90 mL of acetone was added, and the mixture was vigorously shaken until the phase separation was no longer present. This mixture was evenly distributed among 10 centrifuge tubes and each tube was centrifuged at 4,500 rpm for 3 minutes. Two pellets were combined into one tube using 10 g of the formulation from Example 26 and 2 g of DMSO. The tubes were sonicated on ice for 90 minutes. This mixture was spin coated on a silicon wafer at 1,500 rpm for 60 s. The coated material had a thickness of about 168 nm and an RI at 550 nm of 1.31.

1. A method of forming a low refractive index film, comprising:
applying a composition to a substrate, said composition comprising a metal organic framework in a solvent system, said metal organic framework including an organic linker having a thermal decomposition temperature; and
heating said composition to a temperature of no higher than about 10° C. below said thermal decomposition temperature to form said low refractive index film.

2. The method of claim 1, wherein said organic linker is chosen from dicarboxylic acids, tricarboxylic acids, imidazoles, triazoles, pyridines, or combinations thereof.

3. The method of claim 1, wherein said organic linker is chosen from benzene dicarboxylic acid, maleic acid, biphenyl dicarboxylic acid, trimesic acid, 2,5-dihydroxyterephthalic acid, fumaric acid, ethanedioic acid, propanedioic acid, 4H-imidazole, 1H-1,2,3-triazole, 1H-1,2,4-triazole, 4,4-bipyridine, 4,4-azopyridine, 2-methylimidazole, naphthalene dicarboxylic acid, aminoterphthalic acid and its derivatives, sulfoterephthalate and its derivatives, or combinations thereof.

4. The method of claim 1, wherein said metal organic framework comprises a metal chosen from Li, Na, K, Rb, Cs, Fr, Be, Mg, Ca, Sr, Ba, Ra, Sc, Y, Ti, Zr, Hf, La, Ac, V, Nb, Ta, Ce, Th, Cr, Mo, W, Pr, Pa, Mn, Tc, Re, Nd, U, Fe, Ru, Os, Pm, Np, Co, Rh, Ir, Sm, Pu, Ni, Pd, Pt, Eu, Am, Cu, Ag, Au, Gd, Cm, Zn, Cd, Hg, Tb, B, Al, Ga, In, TI, Dy, Si, Ge, Sn, Pb, Ho, As, Sb, Bi, Er, Te, Po, Tm, At, Yb, Lu, or combinations thereof.

5. The method of claim 1, wherein said metal organic framework further comprises an endcap chosen from alkyl carboxylic acids, aryl carboxylic acids, and combinations thereof.

6. The method of claim 5, wherein said endcap is chosen from trifluoroacetic acid, 9-anthracene carboxylic acid, alkoxy silanes, butyl glycidyl ether, acetic acid, formic acid, dichloroacetic acid, proline, phenylalanine, glycine, hydrochloric acid, or combinations thereof.

7. The method of claim 1, wherein said composition further comprises a catalyst, a crosslinker, a silane, or combinations of the foregoing.

8. The method of claim 7, wherein said crosslinker comprises at least two functional groups chosen from vinyl groups, epoxy groups, hydroxy groups, carboxy groups, amine groups, or combinations thereof.

9. The method of claim 7, wherein said crosslinker is chosen from glycidyl polyhedral oligomeric silsesquioxane, methacrylate polyhedral oligomeric silsesquioxane, divinylbenzene, glycidyl methacrylate, bismaleimide compounds, solgel derived siloxanes, or combinations thereof.

10. The method of claim 1, wherein said metal organic framework comprises:
zirconium oxide clusters coordinated with an organic linker chosen from benzene dicarboxylic acid, maleic acid, biphenyl dicarboxylic acid, or combinations thereof; and
an endcap reacted with said organic linker and chosen from trifluoroacetic acid, 9-anthracene carboxylic acid, butyl glycidyl ether, methyltrimethoxysilane, tetraethoxysilane, or combinations thereof.

11. The method of claim 10, wherein said composition further comprises a crosslinker chosen from glycidyl polyhedral oligomeric silsesquioxane, methacrylate polyhedral oligomeric silsesquioxane, divinylbenzene, glycidyl methacrylate, solgel derived siloxanes, or combinations thereof.

12. The method of claim 1, wherein said metal organic framework has an average size of about 1 nm to about 20 nm and/or an average pore size of about 1 nm to about 3 nm.

13. The method of claim 1, wherein said low refractive index film has a refractive index of about 1.35 or lower at a wavelength of about 200 nm or greater.

14. The method of claim 1, wherein said temperature is about 125° C. or lower.

15. The method of claim 1, wherein said low refractive index film is crosslinked during said heating.

16. The method of claim 1, wherein said substrate is chosen from glass, polycarbonate, one or more micro lenses, a lens body, patterned substrates, silicon nitride, or high RI substrates.

17. A structure comprising a low refractive index film on a substrate, wherein:
said low refractive index film:
comprises a metal organic framework comprising a plurality of metal clusters coordinated to respective organic linkers, the majority of said metal clusters being crosslinked with at least one other metal cluster; and
has a refractive index of about 1.35 or lower at a wavelength of about 200 nm or greater; and
said substate is chosen from glass, polycarbonate, one or more micro lenses, a lens body, patterned sustrates, silicon nitride, or high RI substrates.

18. The structure of claim 17, wherein:
said organic linker is chosen from benzene dicarboxylic acid, maleic acid, biphenyl dicarboxylic acid, trimesic acid, 2,5-dihydroxyterephthalic acid, fumaric acid, ethanedioic acid, propanedioic acid, 4H-imidazole, 1H-1,2,3-triazole, 1H-1,2,4-triazole, 4,4-bipyridine, 4,4-azopyridine, 2-methylimidazole, naphthalene dicarboxylic acid, aminoterphthalic acid and its derivatives, sulfoterephthalate and its derivatives, or combinations thereof; and
said metal clusters comprise a metal chosen from Li, Na, K, Rb, Cs, Fr, Be, Mg, Ca, Sr, Ba, Ra, Sc, Y, Ti, Zr, Hf, La, Ac, V, Nb, Ta, Ce, Th, Cr, Mo, W, Pr, Pa, Mn, Tc, Re, Nd, U, Fe, Ru, Os, Pm, Np, Co, Rh, Ir, Sm, Pu, Ni, Pd, Pt, Eu, Am, Cu, Ag, Au, Gd, Cm, Zn, Cd, Hg, Tb, B, Al, Ga, In, Tl, Dy, Si, Ge, Sn, Pb, Ho, As, Sb, Bi, Er, Te, Po, Tm, At, Yb, Lu, or combinations thereof.

19. The structure of claim 17, wherein said crosslinker is chosen from glycidyl polyhedral oligomeric silsesquioxane, methacrylate polyhedral oligomeric silsesquioxane, divinylbenzene, glycidyl methacrylate, solgel derived siloxanes, or combinations thereof.

20. The structure of claim 17, wherein said metal organic framework further comprises an endcap bonded with some of said organic linkers.

21. The structure of claim 20, wherein said endcap is chosen from trifluoroacetic acid, 9-anthracene carboxylic acid, alkoxy silanes, butyl glycidyl ether, acetic acid, formic acid, dichloroacetic acid, proline, phenylalanine, glycine, hydrochloric acid, or combinations thereof.

22. The structure of claim 17, wherein said metal organic framework has an average size of about 1 nm to about 20 nm and/or an average pore size of about 1 nm to about 3 nm.
